(19) United States
(12) Patent Application Publication
(10) Pub. No.: US 2025/0085624 A1
(43) Pub. Date: Mar. 13, 2025

(54) PELLICLE, EXPOSURE ORIGINAL PLATE, EXPOSURE APPARATUS, METHOD FOR PRODUCING PELLICLE, AND METHOD FOR TESTING ADHESIVE LAYER FOR MASK

(71) Applicant: Mitsui Chemicals, Inc., Chuo-ku, Tokyo (JP)

(72) Inventor: Ryo TANAKA, Chiyoda-ku, Tokyo (JP)

(73) Assignee: Mitsui Chemicals, INC., Chuo-ku, Tokyo (JP)

(21) Appl. No.: 18/726,479

(22) PCT Filed: Jan. 26, 2023
(86) PCT No.: PCT/JP2023/002471

§ 371 Date: Jul. 3, 2024

(30) Foreign Application Priority Data
Feb. 4, 2022 (JP) 2022-016687

(51) Int. Cl. G03F 1/64; G03F 1/84

(52) U.S. Cl. CPC G03F 1/64; G03F 1/84

(57) ABSTRACT

Provided is a pellicle, including a frame on which a pellicle film is placed and a mask adhesive layer which is placed on the frame, wherein when a water washing test is performed on the adhesive layer, which contacts a quartz mask over a predetermined contact area, a removal ratio {(the contact area before the water washing test−contact area after the water washing test)/(contact area before the water washing test)} of the adhesive layer is 80% or more.

### FIELD

The present invention relates to a pellicle, an exposure master, and an exposure device, as well as a pellicle production method and a test method for a mask adhesive layer.

### BACKGROUND

In a lithographic step for producing electronic components, pellicles are sometimes used to protect photomasks from dust. A pellicle includes a frame on which a pellicle film is placed, and a mask adhesive layer which is placed on the frame, and is attached to a photomask via the mask adhesive layer.

When the mask adhesive layer receives stray light during exposure, it tends to react with the surface of the photomask, and as a result, the adhesion thereof to the photomask tends to increase. In this case, even when the pellicle has been peeled off from the photomask, there is a risk that the adhesive of the mask adhesive layer may remain on the photomask, resulting in so-called “adhesive residue.” In recent years, as the wavelength of exposure light has become shorter, the frequency of replacing photomasks has increased.

There has been proposed a pellicle one of which objects is to reduce adhesive residue (refer to Patent Literature 1). Patent Literature 1 proposes controlling the content of carboxylic acid-containing monomer units in a mask adhesive layer to 0.9% by mass or less based on 100% by mass of a (meth)acrylic acid alkyl ester copolymer.

### CITATION LIST

### Patent Literature

[PTL 1] Japanese Unexamined Patent Publication (Kokai) No. 2017-90719

### SUMMARY

### Technical Problem

However, there is a background in which it is difficult to completely remove the adhesive residue in the prior art as described in Patent Literature 1, and thus, it is necessary to remove the mask adhesive layer on the photomask each time the photomask is replaced. Even if it is assumed that a technique capable of further reducing adhesive residue is created and used, the operation of removing the mask adhesive layer on the photomask each time the photomask is replaced will be performed as usual as a preliminary operation.

In light of such circumstances, in order to further improve the efficiency of photomask replacement operations, it is necessary to focus on a different perspective than reducing adhesive residue.

The present invention has been conceived in light of the circumstances described above, and an object of the present invention is:
to provide a pellicle with which the efficiency of photomask replacement operations can be further improved by focusing on a typical quartz mask as the photomask and using a mask adhesive layer which is easy to remove from the quartz mask by washing with water.

Another object of the present invention is to provide an exposure master and an exposure device using the above pellicle, a method for the production of the pellicle, and a test method for a mask adhesive layer.

### Solution to Problem

Examples of embodiments according to the present invention are as described below.

[1]

A pellicle, comprising a frame on which a pellicle film is placed, and a mask adhesive layer placed on the frame, wherein
when a water washing test is performed on the adhesive layer, which contacts a quartz mask over a predetermined contact area A1, a removal ratio {(the contact area A1 before the water washing test−contact area A2 after the water washing test)/(the contact area A1 before the water washing test)} of the adhesive layer is 80% or more.
   [2]

The pellicle according to Item 1, wherein the adhesive layer contains a reaction product of a (meth)acrylic copolymer and a curing agent.

[3]

The pellicle according to Item 2, wherein the curing agent is an isocyanate compound.

[4]

The pellicle according to Item 2 or 3, wherein a ratio of the curing agent to the total amount of the (meth)acrylic copolymer is 0.10 to 3.00% by mass.

[5]

The pellicle according to any one of Items 1 to 4, wherein the water washing test is performed by immersing the mask in a water tank for 10 minutes and then extracting the mask from the water tank.

[6]

The pellicle according to any one of Items 1 to 5, wherein the contact area A1 before the water washing test is a residual area of the adhesive layer on the mask when an attachment portion of the adhesive layer to the mask is irradiated with VUV (Vacuum UltraViolet) light from a back side of the mask for 1 minute and the pellicle is then peeled off.

[7]

The pellicle according to Item 6, wherein the contact area A1 before the water washing test is the residual area when the attachment portion is irradiated with the VUV light for 1 minute and the pellicle is then peeled off.

[8]

The pellicle according to Item 6, wherein the contact area A1 before the water washing test is the residual area of the adhesive layer on the mask when the attachment portion of the adhesive layer to the mask is irradiated with VUV (Vacuum UltraViolet) light from a back surface of the mask at a cumulative radiation dose of 3.0 J/cm² and the pellicle is then peeled off.

[9]

The pellicle according to any one of Items 1 to 8, wherein the removal ratio of the adhesive layer is 90% or more.

[10]

The pellicle according to Item 1 or 2, wherein the water washing test is performed based on the following steps (A) to (D):
(A) immersing the quartz mask and the adhesive layer in contact with the quartz mask in water;
(B) rubbing the adhesive layer with a finger when the adhesive layer is in contact with the quartz mask in the water tank after 5 minutes from the start of immersion;
(C) extracting the quartz mask into the atmosphere after 10 minutes from the start of immersion; and
(D) rubbing the adhesive layer with a finger when the adhesive layer is in contact with the quartz mask in the atmosphere.
   [11]

An exposure master comprising the quartz mask and the pellicle according to any one of Items 1 to 9 mounted to the mask.

[12]

An exposure device, comprising:
a light source for emitting VUV (Vacuum UltraViolet) light, and the exposure master according to Item 11, which is irradiated with the VUV light.
   [13]

A method for the production of a pellicle comprising a frame on which a pellicle film is placed, and a mask adhesive layer placed on the frame, wherein
when a water washing test is performed on the adhesive layer, which contacts a quartz mask over a predetermined contact area A1, a removal ratio {(the contact area A1 before the water washing test−contact area A2 after the water washing test)/(the contact area A1 before the water washing test)} of the adhesive layer is 80% or more.
   [14]

A test method for a mask adhesive layer of a pellicle comprising a frame on which a pellicle film is placed, and a mask adhesive layer placed on the frame, wherein
when a water washing test is performed on the adhesive layer, which contacts a quartz mask over a predetermined contact area A1, a value based on a removal ratio {(the contact area A1 before the water washing test−contact area A2 after the water washing test)/(the contact area A1 before the water washing test)} of the adhesive layer is compared with a predetermined threshold.
   [15]

A method for peeling a mask adhesive layer of a pellicle comprising a frame on which a pellicle film is placed, and a mask adhesive layer which is placed on the frame, from a quartz mask, the method comprising:
a step of irradiating an attachment portion of the adhesive layer to the mask with VUV (Vacuum Ultra Violet) light, and thereafter, a step of washing with water.
   [16]

The method for peeling a mask adhesive layer according to Item 15, wherein in the VUV light irradiation step, the attachment portion of the adhesive layer to the mask is irradiated with the VUV light from a back surface of the mask for 1 minute, and the pellicle is then peeled off.

[17]

The method for peeling a mask adhesive layer according to Item 15 or 16, wherein in the VUV light irradiation step:
the attachment portion of the adhesive layer to the mask is irradiated with the VUV light from a back surface of the mask at a cumulative radiation dose of 3.0 J/cm² and the pellicle is then peeled off.

### Advantageous Effects of Invention

According to the present invention, there can be provided a pellicle with which the efficiency of photomask replacement operations can be further improved by focusing on a typical quartz mask as the photomask and using a mask adhesive layer which is easy to remove from the quartz mask by washing with water. Furthermore, according to the present invention, there can be provided an exposure master and an exposure device using the pellicle described above, as well as a method for the production of the pellicle and a test method for a mask adhesive layer.

### BRIEF DESCRIPTION OF DRAWINGS

FIG. 1 is a view showing a configuration example of an exposure device and an exposure master according to the present embodiment.

FIGS. 2A and 2B are views showing a configuration example of a pellicle according to the present embodiment.

FIGS. 3A and 3B are views showing a configuration example of a pellicle according to the present embodiment.

FIGS. 4A and 4B are views showing a configuration example of a test method according to the present embodiment.

### DESCRIPTION OF EMBODIMENTS

Embodiments of the present invention (hereinafter referred to as the “present embodiment”) will be described below. In the present embodiment, numerical ranges described using “to” represent numerical ranges including the numerical values before and after “to.” In the present embodiment, the upper limit or lower limit described in a certain numerical range can be replaced with the upper limit or lower limit of another numerical range. In the present embodiment, the upper limit value or lower limit value described in a certain numerical range can be replaced with the values shown in the Examples. In the present embodiment, the term “step” includes not only independent steps but also steps which cannot be clearly distinguished from other steps, as long as the function of the step is achieved. The scale, shape, and length of each part in the drawings may be exaggerated for added clarity.

### [Exposure Device and Exposure Master]

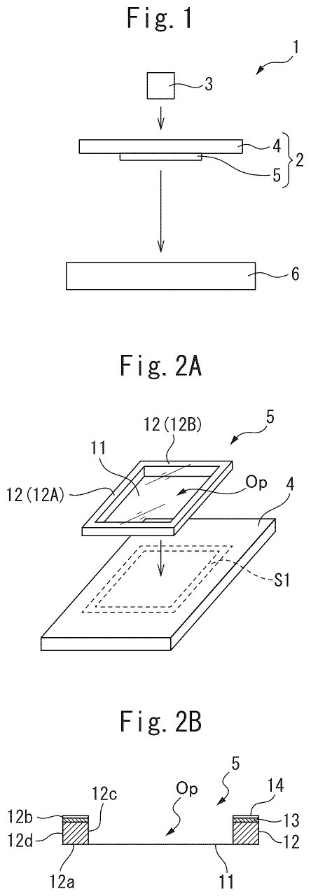

FIG. 1 is a schematic view showing a configuration example of an exposure device 1 and an exposure master 2 according to the present embodiment. As shown in the drawing, the exposure device 1 comprises a light source 3 for emitting light and the exposure master 2, which is irradiated with the light, wherein the exposure master 2 comprises a photomask 4 and a pellicle 5 mounted to the photomask 4.

The light emitted from the light source 3 is VUV (Vacuum UltraViolet) light, and the photomask 4 is made of quartz. Hereinafter, a photomask composed of quartz may be referred to as a quartz mask.

The pellicle 5 is attached to the photomask 4 so as to cover a circuit pattern (not illustrated) formed on the photomask 4. The pellicle 5 functions as a dustproof cover for the photomask 4. In the exposure device 1, the light emitted from light source 3 (the arrow in FIG. 1) passes through the circuit pattern of the photomask 4, further transmits through the pellicle film of the pellicle 5, and is guided to the photoresist (not illustrated) on a stage 6.

Since the exposure device 1 and the exposure master 2 include the pellicle 5 according to the present embodiment, the mask adhesive layer can easily be removed from the photomask 4, and as a result, it is possible to further improve the efficiency of the photomask 4 replacement operation.

### [Pellicle]

### [Schematic Configuration]

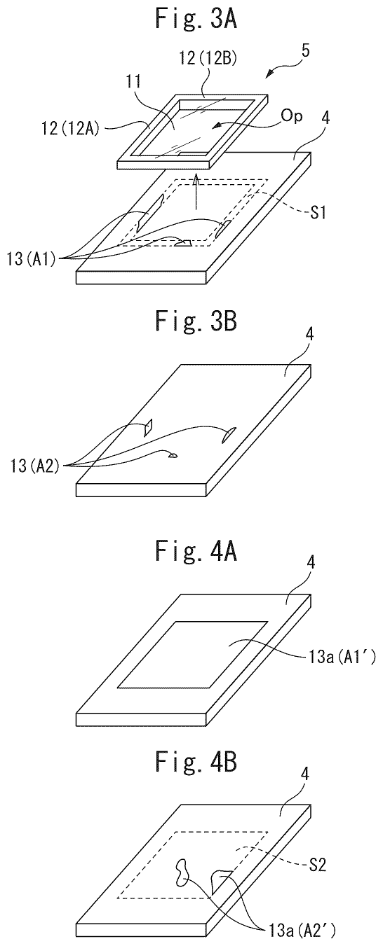

FIGS. 2 and 3 are views showing configuration examples of the pellicle 5 according to the present embodiment. Thereamong, FIG. 2(a) shows an example of the configuration when the pellicle 5 is attached to the photomask 4, and FIG. 2(b) shows an example of the configuration of the cross section of the pellicle 5. FIG. 3(a) shows an example of the configuration when peeling the pellicle 5 from the photomask 4, and FIG. 3(b) shows an example of the configuration of the pellicle 5 (mask adhesive layer) after a water washing test. In FIGS. 2 and 3, the attachment portion S1 of the pellicle 5 to the photomask 4 is represented by a dotted line.

As illustrated, the pellicle 5 comprises a frame 12 on which a pellicle film 11 is placed, and a mask adhesive layer (hereinafter sometimes simply referred to as “adhesive layer”) 13 placed on the frame 12. In the pellicle 5, when a water washing test is performed on the adhesive layer 13, which contacts the photomask 4 over a predetermined contact area A1, the removal ratio of the adhesive layer 13 is 80% or more.

According to the above configuration, by adopting the technical approach ofusing an adhesive layer 13 which is easy to remove from the photomask 4, it is possible to further improve the efficiency of the photomask 4 replacement operation.

### [Frame]

The frame 12 is a member for supporting the pellicle film 11. The frame 12 comprises a pair of sides 12A and a pair of sides 12B. The sides 12A may be the long sides, and the sides 12B may be the short sides. These long sides 12A and short sides 12B form a rectangular outer shape, and a rectangular opening Op is formed inside the outer shape.

Both the long sides 12A and the short sides 12B have a substantially rectangular parallelepiped shape. The long sides 12A and the short sides 12B each have four faces (one face 12a, the other face 12b opposite to the one face 12a, an inner circumferential face 12c, and an outer circumferential face 12d opposite to the inner circumferential face 12c). The one face 12a includes the area where the pellicle film 11 is attached, and the other face 12b includes the area where the adhesive layer 13 is formed.

The length of the long sides 12A is, for example, 50 mm or more, 80 mm or more, or 100 mm or more, and 200 mm or less, 180 mm or less, or 160 mm or less. The length of the short sides 12B is 30 mm or more, 50 mm or more, or 80 mm or more, and 180 mm or less, 160 mm or less, or 140 mm or less. According to the lengths of the long sides 12A and/or the short sides 12B, it is easy to prevent the pellicle film 11 from sagging, and it is also easy to surround the circuit pattern formed on the photomask 4.

However, the configuration of the frame 12 (length, width, thickness, shape, etc.) can be arbitrarily changed in accordance with the configuration of the pellicle film 11, the size of the circuit pattern formed on the photomask 4, etc. The frame 12 may be configured integrally or may be configured so as to be divisible.

The frame 12 can be formed of known materials, such as:
aluminum;
aluminum alloys (for example, 5000 series, 6000 series, 7000 series, etc.);
steel;
stainless steel;
magnesium alloys;
ceramics such as silicon carbide (SiC), aluminum nitride (AlN), and aluminum oxide (Al₂O₃);
composite materials of a ceramic and a metal (for example, Al—SiC, Al—AlN, Al—Al₂O₃, etc.);
engineered plastics using polyethylene (PE), polyamide (PA), polycarbonate (PC), or polyetheretherketone (PEEK);
fiber composite materials such as glass fiber reinforced plastic (GFRP) and carbon fiber reinforced plastic (CFRP); or
combinations of these.

The inner circumferential face 12c of the frame 12 may include an adhesive component for trapping foreign matter, if necessary. Examples of the adhesive component include:
acrylic-based, vinyl acetate-based, silicone-based, and rubber-based adhesives; and
silicone-based or fluorine-based grease.

### [Pellicle Film]

The pellicle film 11 is a transparent thin film. The pellicle film 11 covers the opening Op. The pellicle film 11 is attached onto the one face 12a of the frame 12 with a pellicle film adhesive (not illustrated) under a certain amount of tension so as not to sag excessively due to the weight of the film itself.

The pellicle film 11 can be formed from nitrocellulose, cellulose derivatives, or fluorine polymers. From the viewpoints of transmittance of light emitted from the light source, light resistance to such light, and self-supporting property of the pellicle film 11 itself, the thickness of the pellicle film 11 is, for example, 10 μm or less. It is preferably 5 μm or less, and more preferably 1 μm or less.

### [Protective Film]

The pellicle 5 may include a protective film 14 (liner) laminated on the adhesive layer 13. The protective film 14 protects the adhesive layer 13 during storage or transportation of the pellicle 5, and is peeled off from the adhesive layer 13 when the pellicle 5 is mounted to the photomask 4.

The protective film 14 can be formed of resin such as polyester, and has a thickness of, for example, 30 to 200 μm. The protective film 14 may have a silicone layer or a fluorine layer on the surface in contact with the adhesive layer 13 to improve peelability.

### [Mask Adhesive Layer]

### <Removal Ratio>

The adhesive layer 13 is a member for attaching the frame 12 to the photomask 4. The adhesive layer 13 can be placed on the other face 12b of the frame 12. In the pellicle 5, when a water washing test is performed on the adhesive layer 13, which contacts the photomask 4 over the contact area A1, the removal ratio of the adhesive layer 13 is 80% or more. The removal ratio is determined from the following formula:

Removal ratio=(contact area A1 before water washing test−contact area A2 after water washing test)/(contact area A1 before water washing test)

For example, when approximately 90% of the adhesive layer 13 on the photomask 4 is removed in the water washing test, the removal ratio is expected to be approximately 90%, and at least 80% or higher.

By the removal ratio of the adhesive layer 13 being 80% or more, the operation of removing the adhesive layer 13 on the photomask 4 can be shortened in time and/or simplified, whereby the effort required for the removal operation can be reduced. When the removal ratio is sufficiently large, the adhesive layer 13 can be easily removed from the photomask 4 even if a mask adhesive layer in a form which tends to leave adhesive residue and/or a lithography step under conditions that tend to leave adhesive residue are employed. From the foregoing, it is expected that the operation of replacing the photomask 4 will become more efficient. From the same viewpoint, the removal ratio is preferably 85% or more, 90% or more, 95% or more, or 98% or more. The removal ratio may be 100% or less than 100%.

In an embodiment, the “adhesive layer, which contacts the photomask over a predetermined contact area A1” is the adhesive layer 13 remaining on the photomask 4. When attaching the adhesive layer 13 to the photomask 4 (refer to FIG. 2(a)), and thereafter the adhesive layer 13 is peeled off from the photomask 4 (refer to FIG. 3(a)), the residual area of the adhesive layer 13 remaining on the photomask 4 can be treated as the contact area A1.

According to this, it is easy to calculate the removal ratio in consideration of the actual lithography step.

In another embodiment, the “adhesive layer, which contacts the photomask over a predetermined contact area A1” is a mask adhesive layer formed on the photomask 4. When the mask adhesive layer is applied directly onto the photomask 4, the area of the adhesive layer can be treated as the contact area A1 (contact area A1′ shown in FIG. 4) described above.

According to this, it is easy to set the contact area A1 to a predetermined fixed value.

The contact area A1 may be roughly calculated by visual inspection, and may be calculated in detail by image analysis of the photomask 4.

The “water washing test” is a test in which water is applied to the photomask 4 to which the adhesive layer 13 adheres. The water washing test is performed using the method described in the Examples.

The “contact area A2 after the water washing test” is the area of the adhesive layer 13 in contact with the photomask 4 after performing the water washing test. The contact area A2 may be roughly calculated by visual observation (refer to FIG. 3(b)), and may be calculated in detail by image analysis of the photomask 4.

### <Residual Area>

The contact area A1 before the water washing test is preferably:
the residual area of the adhesive layer 13 on the photomask 4 when the attachment portion S1 of the adhesive layer 13 to the photomask 4 is irradiated with VUV light from a back surface of the photomask 13 for 1 minute and the pellicle 5 is then peeled off.

The “back surface of the photomask” in FIG. 2 corresponds to the surface of the photomask 4 opposite to the surface to which the adhesive layer 13 is attached. Using an exposure device 1 as shown in FIG. 1, VUV light is emitted for 1 minute under a normal environment and normal operation in accordance with an actual lithography step. The pellicle 5 is then peeled off from the photomask 4 under a normal environment and under normal operation in accordance with an actual lithography step. “When . . . is irradiated with VUV light from the back surface of the photomask for 1 minute and then pellicle is peeled off” is realized by means of the foregoing. Note that peeling can be performed by pulling up the pellicle 5 perpendicularly to the photomask 4 at a rate of 1 to 10 mm/min using a known tensile testing machine.

The “residual area of the mask adhesive layer on the photomask” corresponds to the area of the adhesive layer 13 remaining on the photomask 4 after the peeling described above. The residual area described above is also understood as a so-called “adhesive residue area.” This residual area, for example, can be roughly calculated visually and can be calculated in more detail by image analysis of the photomask 4.

The irradiation time of VUV light is 1 minute. The longer the irradiation time with the VUV light, the more easily the adhesive layer 13 can be cured. According to this, it is easy to calculate the removal ratio in consideration of the actual lithography step. In the pellicle 5 according to the present embodiment, the removal ratio of the adhesive layer 13 can easily be calculated even when a short irradiation time of 1 minute is selected for the VUV light.

The thickness of the adhesive layer 13 may be, for example, 0.15 to 3.0 mm, and can be appropriately selected depending on the field and/or application of the final product realized through the lithographic step. When performing lithography for obtaining a semiconductor device, the thickness of the adhesive layer 13 suitable for the photomask used in the lithography is, for example, 0.15 mm or more, 0.20 mm or more, or 0.25 mm or more, and 1.0 mm or less, 0.8 mm or less, or 0.7 mm or less. When performing lithography for obtaining a liquid crystal device, the thickness of the adhesive layer 13 suitable for the photomask used in the lithography is, for example, 0.80 mm or more, 1.0 mm or more, or 1.2 mm or more, and 3.0 mm or less, 2.5 mm or less, or 2.0 mm or less.

The cross-sectional direction flatness of the adhesive layer 13 may be 1 μm or more, or 2 μm or more, and may be 20 μm or less, 15 μm or less, or 13 μm or less. When the cross-sectional direction flatness of the adhesive layer 13 is 1 μm or more, even if air bubbles entrapped when attaching the pellicle 5 to the photomask 4, it becomes easy to ensure suitable passages for the escape of the air bubbles. When the cross-sectional direction flatness of the adhesive layer 13 is 20 μm or less, the load when attaching the pellicle 5 to the photomask 4 is likely to be uniformly applied to the adhesive layer 13 and, by extension, the photomask 4.

The “cross-sectional direction of the mask adhesive layer” corresponds to the thickness direction of the frame 12. The cross-sectional direction flatness of the adhesive layer 13 can be derived by the following method. The cross section of the adhesive layer 13 placed on the frame 12 is observed at a plurality of arbitrary points (for example, 10 points, 12 points, 15 points, or 20 points). In each cross section, the difference between the maximum thickness and the minimum thickness (height difference) is determined. The average value of the height differences obtained by the number of the plurality of points is then determined. This average value corresponds to the flatness described above.

The thickness and, by extension, the flatness of the adhesive layer 13, can be measured using a laser displacement meter. For a pellicle 5 having a protective film 14, the flatness may be measured after peeling off the protective film 14. If the flatness is not affected by the protective film 14, the flatness may be measured for the pellicle having the protective film 14.

### <Method for Peeling Mask Adhesive Layer>

Another aspect of the present embodiment provides a method for peeling the adhesive layer 13. This peeling method includes the steps of irradiating the attachment portion of the adhesive layer 13 to the photomask 4 with VUV light, and thereafter, washing with water. Based on the above steps, the adhesive layer 13 can conveniently be peeled off from the photomask 4 by washing with water. Thus, the risk of damage to the photomask 4 and the incidence of haze during exposure are reduced as compared to, for example, when using acid to clean the mask or forcefully peeling the mask adhesive layer from the photomask.

In the VUV light irradiation step:
it is preferable that the attachment portion of the adhesive layer to the mask be irradiated with VUV light from the back surface of the mask for 1 minute and the pellicle then be peeled off. According to this, the adhesive layer 13 can easily be peeled off from the photomask 4 by washing with water.

In the VUV light irradiation step:
it is preferable that the attachment portion of the adhesive layer to the mask be irradiated with VUV light from the back surface of the mask at a cumulative radiation dose of 3.0 J/cm² and the pellicle then be peeled off. According to this, it is easier to suitably peel the adhesive layer 13 from the photomask 4 by washing with water.

The adhesive layer 13 can include, for example, a structure derived from each of:
a component (A): a primary agent having a specific functional group, and
a component (B): a curing agent having reactivity with the specific functional group.

In other words, the adhesive layer 13 can be configured to include a reaction product of the component (A) and the component (B). Various physical properties of the adhesive layer 13 can be controlled by the respective types and/or ratios of the component (A) and the component (B), whereby the removal ratio can be controlled.

The adhesive layer 13 includes, for example, an acrylic copolymer. Acrylic copolymers have various physical properties that can easily be controlled, and their raw materials are also easy to procure.

The ratio of the component (A) to the total amount of the adhesive layer 13 is preferably 98.0% by mass or more, or 99.0% by mass or more, and preferably 99.9% by mass or less, or 99.8% by mass or less. When the ratio of the component (A) is within the above range, suitable adhesion of the adhesive layer 13 to the photomask 4 and appropriate peelability of the adhesive layer 13 from the photomask 4 are more likely to be exhibited, and it is easy to remove the adhesive layer 13 from the photomask 4.

### <Component (A): Primary Agent)>

The component (A) contains, for example, a (meth)acrylic copolymer, and specifically, a (meth)acrylic acid ester copolymer. In an embodiment, the (meth)acrylic ester copolymer is a copolymer of a (meth)acrylic ester and a monomer having a specific functional group. Among them, a copolymer obtained using a mixture containing 80 to 99% by mass of a (meth)acrylic acid ester and 1 to 20% by mass of a monomer having a specific functional group is preferable from the viewpoint of developing appropriate adhesion to the photomask 4.

The weight average molecular weight of the component (A) is, for example, 700,000 to 2,500,000, and in this case, the cohesive force of the adhesive layer 13 and/or the adhesive force of the adhesive layer 13 to the photomask 4 can easily be controlled to an appropriate level. From the same viewpoint as above, the weight average molecular weight of the component (A) is 900,000 or more, or 1,050,000 or more, and 2,000,000 or less, or 1,500,000 or less.

The weight average molecular weight of the component (A) tends to increase when, for example, the monomer raw material is subjected to a polymerization reaction wherein the monomer concentration is high, the amount of polymerization initiator is low, or the polymerization temperature is low. Generally, the greater the weight average molecular weight, the greater the cohesive force tends to be, and the greater the cohesive force, the greater the residual stress value tends to be.

The component (A) can be produced using a known polymerization method. Examples of such polymerization methods include radical polymerization, ionic polymerization, living polymerization, and living radical polymerization. In the polymerization, a polymerization initiator, chain transfer agent, emulsifier, etc., may be appropriately selected and used.

### ((Meth)Acrylic Acid Ester)

The (meth)acrylic ester has, for example, an alkyl group having 1 to 14 carbon atoms, and the alkyl group may be linear or branched. However, from the viewpoint of reducing adhesive residue and achieving suitable adhesion to the photomask 4, the alkyl group preferably has 4 to 8 carbon atoms and is linear. One (meth)acrylic acid ester can be used alone or two or more thereof may be used in combination.

Examples of (meth)acrylic esters having a linear alkyl group include methyl (meth)acrylate, ethyl (meth)acrylate, propyl (meth)acrylate, butyl (meth)acrylate, hexyl (meth)acrylate, octyl (meth)acrylate, nonyl (meth)acrylate, decyl (meth)acrylate, and dodecyl (meth)acrylate.

Examples of (meth)acrylic acid esters having a branched alkyl group include isopropyl (meth)acrylate, isobutyl (meth)acrylate, isopentyl (meth)acrylate, 2-ethylhexyl (meth)acrylate, isooctyl (meth)acrylate, and isononyl (meth)acrylate.

### (Monomer Having Specific Functional Group)

The monomer having a specific functional group can be copolymerized with the (meth)acrylic acid ester. The “specific functional group” as used herein refers to a functional group having reactivity with the component (B), such as a carboxyl group (—COOH) and/or a hydroxyl group (—OH). One monomer having a specific functional group can be used alone or two or more thereof may be used in combination.

Examples of monomers having a specific functional group include:
carboxyl group-containing monomers such as (meth)acrylic acid, itaconic acid, maleic acid, and crotonic acid; and
hydroxyl group-containing monomers such as 2-hydroxyethyl (meth)acrylate, 3-hydroxypropyl (meth)acrylate, 2-hydroxypropyl (meth)acrylate, 4-hydroxybutyl (meth)acrylate, and 6-hydroxyhexyl (meth)acrylate.

The photomask 4, which is made of quartz, has a hydroxyl group on its surface. When a reaction occurs between the hydroxyl group in the photomask 4 and the carboxyl group contained in the carboxyl group-containing monomer in the adhesive layer 13, the bond between the photomask 4 and the adhesive layer 13 tends to become strong. Thus, the ratio of the carboxyl group-containing monomer to the total amount of the component (A) is preferably 0.9% by mass or less, 0.5% by mass or less, or 0.3% by mass or less.

When the number of crosslinks due to the reaction between the hydroxyl group contained in the hydroxyl group-containing monomer and the component (B) increases in the unit polymer length of the adhesive layer 13, since the flexibility of the polymer will be impaired, residual stress tends to increase. Furthermore, when the number of hydroxyl groups contained in the hydroxyl group-containing monomer in the component (A) increases, the number of hydroxyl groups remaining after the reaction with the component (B) increases, and the remaining hydroxyl groups are likely to be naturally oxidized or oxidized in an exposed environment, and as a result, the formation of carboxyl groups is more likely to occur. Thus, the ratio of the hydroxyl group-containing monomer to the total amount of the component (A) is preferably 10% by mass or less, 4% by mass or less, or 2% by mass or less.

As the photomask 4, one having a chromium vapor-deposited film formed on its surface may be used. In this case, the light emitted from the light source is blocked by the chromium vapor-deposited film. This prevents a reaction between the photomask 4 and the adhesive layer 13 from being caused by such light. By controlling the ratio of the carboxyl group-containing monomer to the total amount of the component (A) as described above, it is easy to effectively reduce adhesive residue for a photomask 4 in which the chromium vapor-deposited film is omitted. In addition, the adhesive layer 13 can easily be removed from the photomask 4.

### <Component (B): Curing Agent)>

The component (B) has reactivity with the specific functional group of the component (A). Examples of the component (B) include metal salts, metal alkoxides, aldehyde compounds, non-amino resin amino compounds, urea compounds, isocyanate compounds, epoxy compounds, metal chelate compounds, melamine compounds, and aziridine compounds. Among these, an isocyanate compound and/or an epoxy compound are preferable, and an isocyanate compound is more preferable.

The ratio of the component (B) to the total amount of the component (A) is preferably 0.10 to 3.00% by mass. According to this, it is easy to remove the adhesive layer 13 from the photomask 4. From the same point of view, the ratio is more preferably 0.130% by mass or more, or 0.150% by mass or more, and is more preferably 2.00% by mass or less, 1.20% by mass or less, or 1.00% by mass or less.

Examples of the isocyanate compound include:
adducts or isocyanurates such as toluene diisocyanate, diphenylmethane diisocyanate, tolylene diisocyanate, isophorone diisocyanate, and hexamethylene diisocyanate.

Examples of polyfunctional epoxy compounds include neopentyl glycol diglycidyl ether, polyethylene glycol diglycidyl ether, bisphenol A diglycidyl ether, bisphenol F diglycidyl ether, phthalic acid diglycidyl ester, dimer acid diglycidyl ester, triglycidyl isocyanurate, diglycerol triglycidyl ether, sorbitol tetraglycidyl ether, N,N,N′,N′-tetraglycidyl m-xylene diamine, 1,3-bis(N,N-diglycidylaminomethyl)cyclohexane, and N,N,N′,N′-tetraglycidyldiaminodiphenylmethane.

### <Other Components>

The adhesive layer 13 may optionally contain known additives such as fillers, pigments, diluents, anti-aging agents, and UV stabilizers. One type of additive can be used alone, or two or more types thereof may be used in combination.

### [Method for Production of Pellicle]

The production method according to the present embodiment provides:
a method for the production of the pellicle 5, wherein
when a water washing test is performed on the adhesive layer 13, which contacts the photomask 4 over the predetermined contact area A1, the removal ratio of the adhesive layer 13 is 80% or more.

Such a production method can include, for example, the following steps.
First step: a step of obtaining a precursor composition for the adhesive layer 13.
Second step: a step of applying the obtained precursor composition to the frame 12.
Third step: a step of drying the applied precursor composition to obtain the adhesive layer 13.

In the first step, components (A) and (B) are mixed to obtain a precursor composition for the adhesive layer 13. The component (A) and/or the component (B) may be mixed as-is, or may be diluted with a predetermined solvent and then mixed. The precursor composition may further contain a solvent from the viewpoint of controlling the applicability to the frame 12 and/or the thickness of the resulting adhesive layer 13. Examples of these solvents include, but are not limited to, acetone, ethyl acetate, butyl acetate, and toluene.

As described above, various physical properties of the adhesive layer 13 can be controlled by the types and/or ratios of the components (A) and (B), and in turn, the removal ratio can be controlled.

In the second step, the obtained precursor composition is applied to the frame 12. In an embodiment, in the second step, the precursor composition is applied to the other face 12b of the frame 12. As the application method, a method using a dispenser is preferable. At this time, the viscosity of the precursor composition may be 1 P·s or more, or 2 P·s or more, and may be 5 P·s or less, 4 P·s or less, or 3 P·s or less. The viscosity here is obtained at, for example, 25° C. using a B-type viscometer.

In the third step, the applied precursor composition is dried to obtain the adhesive layer 13. This third step can further include the following steps:
Third (1) step: a drying step.
Third (2) step: a molding step.

In the third (1) step, the applied precursor composition is dried to reduce the amount of solvent in the precursor composition. In the third (1) step, the dried precursor composition may be heated to an extent that it can be molded. The heating time may be, for example, 50 to 10,000 seconds, and the heating temperature may be, for example, 50 to 200° C. Heat-drying may be performed on multiple occasions at different heating times or different temperatures.

In the third (2) step, the precursor composition is molded to a predetermined thickness and/or a predetermined width. In the third (2) step, the molded precursor composition may be further heated so that the curing reaction between the components (A) and (B) further proceeds.

The production method according to the present embodiment may further include the following step:
Fourth step: a step of laminating the protective film 14 on the adhesive layer 13.

In the fourth step, the protective film 14 is laminated on the adhesive layer 13. In the fourth step, after laminating the protective film 14, this state may be maintained at room temperature (20±3° C.) for several days. As a result, the adhesive force may be stabilized.

In the production method according to the present embodiment, the attachment of the pellicle film 11 to the frame 12 may be before the first step, between the first step and the second step, between the second step and the third step, between the third step and the fourth step, or after the fourth step.

### Embodiment 2

### [Test Method for Mask Adhesive Layer]

The test method according to the present embodiment provides a test method for a mask adhesive layer. In such a test method, a value based on the removal ratio {(contact area A1 before the water washing test−contact area A2 after the water washing test)/(contact area A1 before the water washing test)} of the adhesive layer when the water washing test is performed on the adhesive layer, which contacts the quartz mask over the predetermined contact area A1, is compared with a predetermined threshold. According to this method, the efficiency of the quartz mask replacement operation can be evaluated.

Note that the mask adhesive layer can be placed on the frame 12 of the pellicle 5, and in an embodiment, it can be placed on the other face 12b of the frame 12.

In the above test method, the value of the obtained removal ratio itself may be compared with the threshold value, or a value correlated with the removal ratio may be compared with the threshold value. The threshold value can be appropriately determined, and when comparing the value of the removal ratio itself with the threshold value, the threshold value is, for example, 80% or more. By the removal ratio being 80% or more, further efficiency of mask replacement operation is expected.

In the test method described above, the attachment portion of the mask adhesive layer to the quartz mask may or may not be irradiated with VUV light from the back surface of the mask. When irradiating with VUV light, the irradiation time is, for example, 30 seconds to 5 minutes, or 30 seconds to 2 minutes, and in an embodiment, is 1 minute. Conditions such as the light emitted from the back surface of the mask and/or the irradiation time can be appropriately selected based on conditions based on an actual lithography step. By performing the above test assuming a normal environment and normal operation based on an actual lithographic step, it is easy to evaluate the efficiency of mask replacement operation in the actual lithographic step.

In an embodiment, the “mask adhesive layer, which contacts the quartz mask over a predetermined contact area A1” in the above test method may be the adhesive layer 13 remaining on the photomask 4 (i.e., the adhesive layer 13 with remaining adhesive) described in embodiment 1 and FIGS. 2 and 3 above. The residual area of the adhesive layer 13 remaining on the photomask 4 can be treated as the contact area A1.

FIGS. 4(a) and 4(b) are views showing an example of another aspect of present embodiment. In FIG. 4(b), the attachment portion SS of the mask adhesive layer to the photomask 4 is represented by a dotted line.

As shown in the drawing, the “mask adhesive layer, which contacts the quartz mask over a predetermined contact area A1” in the above test method may be the adhesive layer 13a formed on the photomask 4. When the adhesive layer 13a is directly applied onto the photomask 4, the area of the adhesive layer 13a can be treated as the contact area A1 (contact area A1′ shown in FIG. 4(a)).

In the present embodiment, as in the embodiment described above, after the water washing test is performed, the area of the adhesive layer 13a in contact with the photomask 4 is treated as the contact area A2 (contact area A2′ shown in FIG. 4(b)).

When the adhesive layer 13a is directly applied onto the photomask 4, the step of placing the adhesive layer 13 on the frame 12, the step of attaching the pellicle 5 to the photomask 4, and the step of peeling the pellicle 5 from the photomask 4 can be omitted. Note that as a method for directly applying the adhesive layer 13a on the photomask 4, a method similar to the method for applying the adhesive layer 13 to the other face 12b of the frame can be adopted.

The present embodiment has been described above. The present embodiment is not limited to the above-described aspects, and various modifications can be made within the scope of the spirit thereof.

### EXAMPLES

Next, the present embodiment will be described in more detail with reference to Examples and Comparative Examples.

### Example 1

### <Preparation of Adhesive Composition>

First, in a reaction vessel equipped with a stirrer, a thermometer, a reflux condenser, a dropping device, and a nitrogen introduction tube, ethyl acetate (30 parts by mass) and raw materials (raw materials for component (A)) listed in the table were charged and reacted for 8 hours at reflux temperature in a nitrogen atmosphere. After the reaction was complete, butyl acetate (33 parts by mass) was added thereto to obtain a solution of a (meth)acrylic acid ester copolymer (component (A)) with a nonvolatile content concentration of 37% by mass. A raw material (component (B)) listed in the table was added to 100 parts by mass of the obtained solution, and the mixture was stirred and mixed to obtain an adhesive composition.

### <Preparation of Pellicle>

Using a dispenser, the adhesive composition prepared as described above was applied onto the other face of an aluminum alloy frame (outer diameter 115 mm×149 mm, inner diameter 111 mm×145 mm, height 3.0 mm) in a state in which the pellicle film was adhered to one face. The applied adhesive composition was heated in two steps (first step: 115° C., 11 minutes; second step: 150° C., 5 minutes) to obtain a mask adhesive layer (thickness 0.20 mm).

Thereafter, a 100 μm thick polyester protective film having a silicone layer formed thereon was laminated on the mask adhesive layer and cured at 100° C. for 12 hours.

From the foregoing, the pellicle of Example 1 was produced.

### [Other Examples] and [Comparative Examples]

Each pellicle was produced in the same manner as in Example 1, except that the raw materials for the component (A) and the raw material for the component (B) were changed as shown in the table.

### <Adhesive Residue>

Each pellicle the Examples and Comparative Examples (for pellicles with a protective film, the pellicle after peeling off the protective film) was loaded (5 kgf, 60 seconds) and attached to a photomask (6025 size, made of quartz) using a simple mounter. As a result, an exposure master having the photomask and the pellicle mounted to the photomask was obtained.

The attachment portion of the mask adhesive layer to the photomask was irradiated with VUV light from the back surface of the photomask for 1 minute, and the pellicle was then peeled off from the photomask. Peeling was performed using a known tensile testing machine by pulling up the photomask perpendicularly at a rate of 5 mm/min. The surface of the photomask was observed visually and using a microscope, and the residual area (contact area A1) of the mask adhesive layer on the photomask was calculated.

Note that the irradiation conditions for the VUV light are as follows.
Light source: Xe
Illuminance: 50 mW/cm²
Cumulative radiation dose: 3.0 J/cm²

### <Water Washing Test>

A water washing test was performed on the photomask on which the mask adhesive layer remained on the photomask according to the method and conditions described below.

Specifically, the photomask on which the mask adhesive layer remained was immersed in a water tank at room temperature for 10 minutes, and then extracted from the water tank. While the photomask was immersed, and after the photomask was extracted from the water tank, the adhesive layer adhering to the photomask was lightly contacted with a finger, palm, or the like.

The specific water washing test method includes the following steps (A) to (D):
(A) immersing the quartz mask and the adhesive layer in contact with the quartz mask in water;
(B) rubbing the adhesive layer with a finger when the adhesive layer is in contact with the quartz mask in the water tank after 5 minutes from the start of immersion;
(C) extracting the quartz mask into the atmosphere after 10 minutes from the start of immersion; and
(D) rubbing the adhesive layer with a finger when the adhesive layer is in contact with the quartz mask in the atmosphere.

In the present water washing test, pure water was used as the water, and both the water temperature and room temperature were adjusted to 24±1° C.

In steps (B) and (D), the adhesive layer was directly rubbed with the pad of a finger 10 times when the adhesive layer was in contact with the quartz mask.

### <Removal Ratio>

After the water washing test, the photomask was observed visually and using a microscope, and the area (contact area A2) of the mask adhesive layer on the photomask was calculated. The removal ratio was calculated using the obtained contact area A2 and the contact area A1 described above. The pellicles of the Examples and Comparative Examples were then evaluated based on the following criteria.
A: Removal ratio was 90% or more
B: Removal ratio was 80% or more and less than 90%
C: Removal ratio was less than 80%

### <Efficiency of Photomask Replacement Operation>

As described above, by reducing adhesive residue, the removal operation of the mask adhesive layer remaining on the photomask can be shortened in time and/or simplified. Thus, the pellicles of the Examples and Comparative Examples were evaluated based on the following criteria.
A: “Removal ratio” was rated A or B, and the adhesive layer could be removed from the photomask without imparting any special vibration to the photomask
B: “Removal ratio” was rated A or B and the adhesive layer could be removed from the photomask by imparting some vibration to the photomask
C: “Removal ratio” was rated C

TABLE 1

| | | | Component (B) | | | Efficiency |
|---|---|---|---|---|---|---|
| | | | | Con - | | of |
| | | | | tent | | photomask |
| | Component (A) | | | (% by | Removal | replacement |
| | Polymer | Ratio | Curing agent | mass) | ratio | operations |
| Ex 1 | BuA/HEA | 99/1 | TPA-100 | 0.20 | A | A |
| Ex 2 | BuA/HEA | 99/1 | MHG | 0.33 | A | A |
| Ex 3 | BuA/HEA | 99/1 | MFA | 0.15 | A | A |
| Ex 4 | BuA/HEA | 99/1 | Coronate L | 0.38 | A | A |

| | | | | | |
|---|---|---|---|---|---|
| Comp | SK Dyne | Coronate L | 0.23 | C | C |
| Ex 1 | 1499M | | | | |
| Comp | SK Dyne | Coronate L | 0.20 | C | C |
| Ex 2 | 1495 | | | | |

BuA: Butyl acrylate
HEA: Hydroxyethyl acrylate
Duranate TPA-100 (manufactured by Asahi Kasei Corporation)
Duranate MHG-80B (manufactured by Asahi Kasei Corporation)
Duranate MFA-80B (manufactured by Asahi Kasei Corporation)
Coronate L (manufactured by Tosoh Corporation)
SK Dyne 1499M (manufactured by Soken Chemical & Engineering Co., Ltd.)
SK Dyne 1495 (manufactured by Soken Chemical & Engineering Co., Ltd.)

As confirmed from the table, the pellicles of the Examples are excellent in “removal ratio.” Thus, by using the pellicles of the Examples, it is expected that the photomask replacement operation will be made more efficient.

### INDUSTRIAL APPLICABILITY

The present invention can suitably be applied in relation to a lithography step for obtaining electronic parts such as integrated circuits (IC), large-scale integration (LSI), and LCD displays (liquid crystal displays). The present invention can suitably be applied to the fields of pellicles, exposure masters, exposure devices, pellicle production methods, and mask adhesive layer test methods.

### DESCRIPTION OF REFERENCE SIGNS

1: exposure device
2: exposure master
3: light source
4: photomask (quartz mask)
5: pellicle
6: stage
11: pellicle film
12: frame
12A: side (long side)
12B: side (short side)
12a: one face
12b: other face
12c: inner circumferential face
12d: outer circumferential face
13, 13a: adhesive layer (mask adhesive layer)
14: protective film
Op: opening
A1 (A1′): contact area before water washing test
A2 (A2′): contact area after water washing test

1. A pellicle, comprising a frame on which a pellicle film is placed, and a mask adhesive layer placed on the frame, wherein
when a water washing test is performed on the adhesive layer, which contacts a quartz mask over a predetermined contact area A1, a removal ratio {(the contact area A1 before the water washing test−contact area A2 after the water washing test)/(the contact area A1 before the water washing test)} of the adhesive layer is 80% or more.

2. The pellicle according to claim 1, wherein the adhesive layer contains a reaction product of a (meth)acrylic copolymer and a curing agent.

3. The pellicle according to claim 2, wherein the curing agent is an isocyanate compound.

4. The pellicle according to claim 2, wherein a ratio of the curing agent to the total amount of the (meth)acrylic copolymer is 0.10 to 3.00% by mass.

5. The pellicle according to claim 1, wherein the water washing test is performed by immersing the mask in a water tank for 10 minutes and then extracting the mask from the water tank.

6. The pellicle according to claim 1, wherein the contact area A1 before the water washing test is a residual area of the adhesive layer on the mask when an attachment portion of the adhesive layer to the mask is irradiated with VUV (Vacuum UltraViolet) light from a back side of the mask for 1 minute and the pellicle is then peeled off.

7. The pellicle according to claim 6, wherein the contact area A1 before the water washing test is the residual area when the attachment portion is irradiated with the VUV light for 1 minute and the pellicle is then peeled off.

8. The pellicle according to claim 6, wherein the contact area A1 before the water washing test is the residual area of the adhesive layer on the mask when the attachment portion of the adhesive layer to the mask is irradiated with VUV (Vacuum UltraViolet) light from a back surface of the mask at a cumulative radiation dose of 3.0 J/cm² and the pellicle is then peeled off.

9. The pellicle according to claim 1, wherein the removal ratio of the adhesive layer is 90% or more.

10. The pellicle according to claim 1, wherein the water washing test is performed based on the following steps (A) to (D):
(A) immersing the quartz mask and the adhesive layer in contact with the quartz mask in water;
(B) rubbing the adhesive layer with a finger when the adhesive layer is in contact with the quartz mask in the water tank after 5 minutes from the start of immersion;
(C) extracting the quartz mask into the atmosphere after 10 minutes from the start of immersion; and
(D) rubbing the adhesive layer with a finger when the adhesive layer is in contact with the quartz mask in the atmosphere.

11. An exposure master comprising the quartz mask and the pellicle according to claim 1 mounted to the mask.

12. An exposure device, comprising:
a light source for emitting VUV (Vacuum UltraViolet) light, and
the exposure master according to claim 11, which is irradiated with the VUV light.

13. A method for the production of a pellicle comprising a frame on which a pellicle film is placed, and a mask adhesive layer placed on the frame, wherein
when a water washing test is performed on the adhesive layer, which contacts a quartz mask over a predetermined contact area A1, a removal ratio {(the contact area A1 before the water washing test−contact area A2 after the water washing test)/(the contact area A1 before the water washing test)} of the adhesive layer is 80% or more.

14. A test method for a mask adhesive layer of a pellicle comprising a frame on which a pellicle film is placed, and a mask adhesive layer placed on the frame, wherein
when a water washing test is performed on the adhesive layer, which contacts a quartz mask over a predetermined contact area A1, a value based on a removal ratio {(the contact area A1 before the water washing test−contact area A2 after the water washing test)/(the contact area A1 before the water washing test)} of the adhesive layer is compared with a predetermined threshold.

15. A method for peeling a mask adhesive layer of a pellicle comprising a frame on which a pellicle film is placed, and a mask adhesive layer which is placed on the frame, from a quartz mask, the method comprising:
a step of irradiating an attachment portion of the adhesive layer to the mask with VUV (Vacuum Ultra Violet) light, and thereafter, a step of washing with water.

16. The method for peeling a mask adhesive layer according to claim 15, wherein in the VUV light irradiation step, the attachment portion of the adhesive layer to the mask is irradiated with the VUV light from a back surface of the mask for 1 minute, and the pellicle is then peeled off.

17. The method for peeling a mask adhesive layer according to claim 15, wherein in the VUV light irradiation step:
the attachment portion of the adhesive layer to the mask is irradiated with the VUV light from a back surface of the mask at a cumulative radiation dose of 3.0 J/cm² and the pellicle is then peeled off.
